(19) United States
(12) Patent Application Publication
(10) Pub. No.: US 2014/0273494 A1
(43) Pub. Date: Sep. 18, 2014

(54) PARALLEL PLATE DRY ETCHING APPARATUS AND METHOD FOR MANUFACTURING SEMICONDUCTOR DEVICE USING SAME

(71) Applicant: Kabushiki Kaisha Toshiba, Minato-ku (JP)

(72) Inventor: Shingo HONDA, Mie-ken (JP)

(73) Assignee: Kabushiki Kaisha Toshiba, Minato-ku (JP)

(21) Appl. No.: 13/948,285

(22) Filed: Jul. 23, 2013

(30) Foreign Application Priority Data
Mar. 12, 2013 (JP) 2013-049367

(51) Int. Cl. H01L 21/3065; H01L 21/67

(52) U.S. Cl. CPC H01L 21/3065; H01L 21/67069
USPC 438/729; 156/345.3

(57) ABSTRACT

According to one embodiment, a parallel plate dry etching apparatus includes: a lower electrode; an upper electrode having a plurality of etching gas supply ports in the lower surface; a reaction chamber including the lower and the upper electrode and having an exhaust port; a flow guide plate disposed in a ring form in an upper portion of a space between a side wall of the reaction chamber and a side wall of the lower electrode, the flow guide plate having a plurality of vent holes; and a pair of shield plates disposed to face the flow guide plate in the space, the pair of shield plates blocking the etching gas passing through part of the plurality of vent holes, and the pair of shield plates facing the lower electrode in a first direction parallel to the upper surface of the lower electrode.

### CROSS-REFERENCE TO RELATED APPLICATIONS

This application is based upon and claims the benefit of priority from Japanese Patent Application No. 2013-049367, filed on Mar. 12, 2013; the entire contents of which are incorporated herein by reference.

### FIELD

Embodiments described herein relate generally to a parallel plate dry etching apparatus and a method for manufacturing semiconductor device using same.

### BACKGROUND

Manufacturing processes of a semiconductor device include a dry etching process for forming a pattern on the surface of a substrate to be processed. In the dry etching process, etching gas in a plasma state is supplied to the surface of the substrate to be processed in a dry etching processing apparatus and thereby the etching of the substrate to be processed is performed. In order that etching may be performed uniformly in the plane of the substrate to be processed, the structure of the surroundings of the substrate to be processed is configured such that etching gas is supplied uniformly in a radial manner from the surface of the substrate to be processed toward the outer periphery of the substrate. However, when miniaturization progresses, in the case where the surface of a substrate to be processed having a mask pattern formed of a plurality of stripes is etched, a portion where the stripe width of a film to be processed after etching is wide and a portion where it is narrow appear alternately in the outer peripheral portion of the substrate to be processed, in the direction orthogonal to the direction in which the stripes of the mask pattern extend. This causes an in-plane variation in the interconnection resistance of a multiple-layer interconnection layer etc. A dry etching apparatus is desired that can suppress the etching variation in the outer peripheral portion of a substrate to be processed.

### BRIEF DESCRIPTION OF THE DRAWINGS

FIG. 1 is a schematic cross-sectional view of a main portion of a parallel plate dry etching apparatus according to a first embodiment;

FIG. 2 is a schematic plan view of the main portion of an interior of a reaction chamber of the parallel plate dry etching apparatus according to the first embodiment;

FIG. 3 is a schematic plan view in which a flow guide plate is removed in FIG. 2;

FIG. 4 is a schematic cross-sectional view of the main portion when area of a shield plates is minimized in the parallel plate dry etching apparatus according to the first embodiment;

FIG. 5 is a schematic plan view of the main portion of the interior of the reaction chamber when the area of the shield plates is minimized in the parallel plate dry etching apparatus according to the first embodiment;

FIG. 6 is a schematic plan view in which the flow guide plate is removed in FIG. 5;

FIG. 7 is a schematic plan view showing a state in which a substrate to be processed is mounted on a lower electrode in a method for manufacturing a semiconductor device using the parallel plate dry etching apparatus according to the first embodiment;

FIG. 8 is a schematic plan view showing a state in which a substrate to be processed is mounted on a lower electrode in a method for manufacturing a semiconductor device using a parallel plate dry etching apparatus according to an comparative example;

FIG. 9 is a schematic cross-sectional view of a main portion of a parallel plate dry etching apparatus according to a second embodiment;

FIG. 10 is a schematic plan view of the main portion of an interior of a reaction chamber of the parallel plate dry etching apparatus according to the second embodiment;

FIG. 11 is a schematic plan view in which a flow guide plate is removed in FIG. 10;

FIG. 12 is a side view as viewed from a direction of an arrow in FIG. 10;

FIG. 13 is a schematic plan view of a main portion of the interior of the reaction chamber when area of a shield plates is minimized in the parallel plate dry etching apparatus according to the second embodiment;

FIG. 14 is a plan view in which the flow guide plate is removed in FIG. 13; and

FIG. 15 is a side view as viewed from a direction of an arrow in FIG. 13.

### DETAILED DESCRIPTION

In general, according to one embodiment, a parallel plate dry etching apparatus includes: a lower electrode having an upper surface in a flat plate form, a substrate being to be mounted on the upper surface in the flat plate form, and the substrate being to be processed; an upper electrode having a lower surface in a flat plate form opposed to the upper surface of the lower electrode and having a plurality of etching gas supply ports in the lower surface; a reaction chamber including the lower electrode and the upper electrode in its interior and having an exhaust port to exhaust the etching gas to an opposite side of the lower electrode against the upper electrode; a flow guide plate disposed in a ring form in an upper portion of a space between a side wall of the reaction chamber and a side wall of the lower electrode, the flow guide plate having a plurality of vent holes to pass through the etching gas, and the flow guide plate surrounding the substrate; and a pair of shield plates disposed to face the flow guide plate in the space, the pair of shield plates blocking the etching gas passing through part of the plurality of vent holes, and the pair of shield plates facing the lower electrode in a first direction parallel to the upper surface of the lower electrode.

Hereinbelow, embodiments of the invention are described with reference to the drawings. The drawings used in the description of the embodiments are schematic for easier description; and in the actual practice, the configurations, dimensions, magnitude relationships, etc. of components in the drawings are not necessarily the same as those illustrated in the drawings and may be appropriately altered to the extent that the effect of the invention is obtained.

### First Embodiment

A parallel plate dry etching apparatus according to a first embodiment of the invention will now be described using FIG. 1 to FIG. 8. FIG. 1 and FIG. 4 are schematic cross-sectional views of a main portion of the parallel plate dry etching apparatus according to the first embodiment. FIG. 2 and FIG. 5 are schematic plan views of a main portion of the interior of a reaction chamber of the parallel plate dry etching apparatus according to the embodiment. FIG. 3 and FIG. 6 are schematic plan views when a flow guide plate 5 is removed in FIG. 2 and FIG. 5, respectively.

As shown in FIG. 1, the parallel plate dry etching apparatus according to the embodiment includes a lower electrode 1, an upper electrode 6, a reaction chamber 4, a flow guide plate 5, and a shield plate 11. The lower electrode 1 has an upper surface in a planar form. A substrate to be processed 2 (a workpiece 2) is mounted on the upper surface. The substrate to be processed 2 has a film to be processed on its surface. A mask pattern is provided on the film to be processed. By dry-etching the film to be processed using the parallel plate dry etching apparatus according to the embodiment, the mask pattern is transferred to the film to be processed.

A ring-like focus ring 3 is provided on the lower electrode 1 so as to surround the periphery of the substrate to be processed 2. The focus ring 3 is preferably fashioned such that the upper surface of the focus ring 3 is disposed in substantially the same plane as the surface of the substrate to be processed. The focus ring 3 is preferably made of the same material as the substrate to be processed 2, but is not necessarily limited thereto. The focus ring 3 may be made of a similar material to the substrate to be processed 2, or the same material as or a similar material to the film to be processed. For example, in the case where the substrate to be processed 2 is silicon (Si), the focus ring 3 may be made of silicon or silicon carbide (SiC). The focus ring 3 is provided in order that the surface of the substrate to be processed 2 may be uniformly etched by plasma-ized etching gas. The focus ring 3 is provided also in order to keep uniform the in-plane temperature distribution of the substrate to be processed 2 or in order to enable positioning with the lower electrode.

The upper electrode 6 has a lower surface in a planar form parallel and opposed to the upper surface of the lower electrode 1. A plurality of etching gas supply ports 6b are provided in the lower surface of the upper electrode 6. The upper electrode 6 includes an etching gas introduction pipe 6a for introducing etching gas into the upper electrode 6. Etching gas is introduced from the etching gas introduction pipe 6a into the upper electrode 6, and is supplied from the etching gas supply ports 6b to the surface of the substrate to be processed 2 mounted on the lower electrode 1.

In the case of a dry etching apparatus of the RIE (reactive ion etching) method, the upper electrode 6 is grounded, and the lower electrode 1 is connected to a high frequency power source 8 via a capacitor 9. In the dry etching apparatus of the RIE method, since electrons are accumulated in the lower electrode by the capacitor 9, the electric potential of the lower electrode 1 drops. Thereby, positive ions in etching gas plasma-ized between the upper electrode 6 and the lower electrode 1 are incident on the substrate to be processed 2 substantially perpendicularly. Thus, the etching is physical and chemical etching, and is anisotropic etching.

In contrast, in the case of the CDE (chemical dry etching) method, a high frequency power source is connected to the upper electrode 6. In a dry etching apparatus of the CDE method, since a potential drop of the lower electrode does not occur, positive ions in etching gas are not substantially perpendicularly incident on the surface of a substrate to be processed. Therefore, chemical etching is predominant over physical etching, and the etching is thus isotropic etching.

Although the parallel plate dry etching apparatus according to the embodiment is described using a dry etching apparatus of the RIE method as an example, it may be used also for a dry etching apparatus of the CDE method.

The reaction chamber 4 includes the lower electrode 1 and the upper electrode 6 in its interior. The reaction chamber has an exhaust port 7 for exhausting etching gas at the bottom, that is, on the opposite side of the lower electrode 1 against the upper electrode 6. The etching gas supplied from the etching gas supply ports 6b of the upper electrode 6 toward the substrate to be processed 2 flows on the surface of the substrate to be processed 2 in a radial manner from the center of the substrate to be processed 2 toward the outer periphery, passes through the ring-like space between the side wall of the reaction chamber 4 and the lower electrode 1, and is exhausted from the exhaust port 7 to the outside of the reaction chamber 4.

The flow guide plate 5 is disposed on the space between the lower electrode 1 and the reaction chamber 4. The flow guide plate 5 is a flat plate in a circular ring form parallel to the upper surface of the lower electrode 1, and surrounds the substrate to be processed 2 and the focus ring 3 in a plane parallel to the upper surface of the lower electrode 1. As shown in FIG. 2, the flow guide plate 5 has a plurality of vent holes 12 penetrating through the flow guide plate 5. The plurality of vent holes 12 are arranged along the circumferential direction of the flow guide plate 5. The etching gas that has flowed radially on the surface of the substrate to be processed 2 passes through the vent holes of the flow guide plate 5, and flows into the space between the lower electrode 1 and the side wall of the reaction chamber 4. The plurality of vent holes 12 are formed in the flow guide plate 5 so that etching gas flows uniformly in a radial manner on the surface of the substrate to be processed 2 in a state where (or when) there is no shield plate 11 described later.

The shield plate 11 is provided to oppose (or to face) the flow guide plate 5 in the space between the lower electrode 1 and the side wall of the reaction chamber 4. The shield plate 11 is, as shown in FIG. 3, a flat plate that is parallel to the upper surface of the lower electrode 1 and has the shape of part of a flat plate in a circular ring form (hereinafter, an arc-like flat plate). The shield plate 11 extends along the side wall of the lower electrode 1 in a plane parallel to the upper surface of the lower electrode 1. The shield plate 11 is provided so as to oppose part of the plurality of vent holes 12 of the flow guide plate 5, and blocks the flow of etching gas that has passed through the part of the vent holes. Consequently, the flow of etching gas from the center of the surface of the substrate to be processed 2 toward the vent holes 12 to which the shield plate 11 is opposed is decreased, and the flow of etching gas from the surface of the substrate to be processed 2 toward the vent holes 12 to which the shield plate 11 is not opposed is increased.

Another identical shield plate 11 is disposed in the space between the lower electrode 1 and the side wall of the reaction chamber 4 so as to oppose the shield plate 11 mentioned above across the lower electrode 1. That is, a pair of shield plates 11 are provided in the space between the lower electrode 1 and the side wall of the reaction chamber 4 so as to sandwich the lower electrode 1 in a first direction parallel to the upper surface of the lower electrode 1. Thereby, on a line in the first direction of the surface of the substrate to be processed 2, the flow of etching gas from the center of the substrate to be processed 2 toward the outside of the substrate to be processed is decreased. In contrast, on a line in a second direction orthogonal to the first direction of the surface of the substrate to be processed 2, the flow of etching gas from the center of the substrate to be processed 2 toward the outside of the substrate to be processed is increased.

The shield plate 11 is supported at the side wall of the lower electrode 1 by a hinge 10 at one end on the lower electrode 1 side. The shield plate 11 can move in the direction perpendicular to the upper surface of the lower electrode 1 with the hinge 10 as a fulcrum by raising and lowering the other end on the opposite side to the lower electrode 1. By the movability of the shield plate 11, the shield plates 11 can alter the area blocking etching gas flowing from the vent holes of the flow guide plate 5. That is, the area of the projection of the shield plates 11 projected onto the flow guide plate 5 can be altered. The shield plates 11 include a means for altering the area blocking the flow of etching gas as mentioned above. The state of the shield plates 11 mentioned above shown in FIG. 1 to FIG. 3 is a state where the area with which the shield plates block the flow of etching gas is at the maximum. At this time, the flow of etching gas in the first direction described above is decreased in the reaction chamber.

In contrast, FIG. 4 to FIG. 6 show a state of the shield plates 11 in the case where the area of the shield plates 11 blocking the flow of etching gas flowing from the vent holes of the flow guide plate 5 is at the minimum. As shown in FIG. 4 and FIG. 6, at this time, the shield plates 11 are folded so as to be parallel to the direction perpendicular to the upper surface of the lower electrode 1 (or a direction parallel to the side surface). As shown in FIG. 5, none of the vent holes 12 of the flow guide plate 5 are opposed to the shield plates 11. At this time, etching gas flows substantially uniformly in a radial manner on the surface of the substrate to be processed 2 from the center of the substrate to be processed 2 toward the outer periphery.

Next, a method for manufacturing a semiconductor device in which a process of dry etching that is part of the manufacturing process of the semiconductor device is performed using the parallel plate dry etching apparatus mentioned above according to the embodiment is described using FIG. 7 and FIG. 8. The parallel plate dry etching apparatus according to the embodiment mentioned above is used in a state where the area with which the shield plates 11 block the flow of etching gas is at the maximum. The shield plate 11 is substantially parallel to the flow guide plate 5. In this case, as described above, the flow of etching gas on the surface of the substrate to be processed 2 is rarely present in the first direction in which the shield plates 11 are disposed, and is predominant in the second direction perpendicular to the first direction. FIG. 7 and FIG. 8 show relationships between the second direction in the reaction chamber in which etching gas flows and the direction in which a mask pattern 13 in a striped configuration formed on the surface of the substrate to be processed 2 mounted on the lower electrode 1 extends.

On the surface of the substrate to be processed 2, for example; a mask pattern 13 in a striped configuration is formed as shown in FIG. 7. In the case of forming a multiple-layer interconnection structure of a semiconductor device, such a mask pattern is used when forming each fine line layer. The arrow shown in FIG. 7 briefly shows the predominant flow of etching gas flowing in the second direction on the surface of the substrate to be processed 1 in the reaction chamber 4 of the parallel plate dry etching apparatus according to the embodiment.

As shown in FIG. 7, in the method for manufacturing a semiconductor device according to the embodiment, the substrate to be processed 2 is mounted on the lower electrode 1 in such a manner that the extending direction of the stripes of the mask pattern 13 of the substrate to be processed 2 is parallel to the second direction in which etching gas in the parallel plate dry etching apparatus according to the embodiment flows predominantly, that is, orthogonal to the first direction. After that, the dry etching of a film to be processed on the surface of the substrate to be processed 2 is performed and the mask pattern 13 is transferred to the film to be processed. By performing dry etching while mounting the substrate to be processed 2 on the lower electrode 1 in this way, the width of the pattern of the film to be processed is made uniform in the surface of the substrate to be processed 2.

In contrast, as shown in FIG. 8, the case is considered where dry etching is performed while the substrate to be processed 2 is mounted on the lower electrode 1 in such a manner that the direction in which the mask pattern 13 formed on the surface of the substrate to be processed 2 extends is orthogonal to the second direction shown by the arrow in the reaction chamber in which etching gas flows predominantly, that is, parallel to the first direction. In this case, in the direction in which the stripes of the mask pattern 13 extend, the width of the mask pattern transferred to the film to be processed is almost uniform near the center and the outer periphery of the substrate to be processed 2. However, in the direction orthogonal to the direction in which the stripes of the mask pattern 13 extend, the stripe width of the mask pattern 13 transferred to the film to be processed becomes larger and smaller alternately in a repeated manner toward the outer periphery side of the substrate to be processed 2. If such a variation occurs in the fine line width in each layer of a multiple-layer interconnection layer, the variation in the resistance value between interconnections will be large.

Therefore, in the case of dry etching in which a pattern in a striped configuration is mainly formed as in the case of a multiple-layer interconnection structure, the substrate to be processed 2 is mounted on the lower electrode 1 preferably in such a manner that the direction in which the mask pattern 13 in a striped configuration formed on the surface of the substrate to be processed 2 extends is orthogonal to the first direction in which the pair of shield plates 11 in the parallel plate dry etching apparatus are opposed to each other.

In the case of forming a conductive via that electrically connects the interconnection between interconnection layers of a multiple-layer interconnection layer in the vertical direction, dry etching is preferably performed such that the pair of shield plates 11 are folded as shown in FIG. 4 to FIG. 6 and the area with which the shield plates 11 block the flow of etching gas is minimized. Unlike the case where the surface of the substrate to be processed 2 has a mask pattern 13 with directivity, in the case of having a mask pattern with no directivity, the width of the pattern of the film to be processed after etching is made more uniform when etching gas flows uniformly in a radial manner on the surface of the substrate to be processed 2.

### Second Embodiment

A parallel plate dry etching apparatus according to a second embodiment will now be described using FIG. 9 to FIG. 15. FIG. 9 is a schematic cross-sectional view of a main portion of the parallel plate dry etching apparatus according to the second embodiment. FIG. 10 is a schematic plan view of a main portion of the interior of the reaction chamber of the parallel plate dry etching apparatus according to the second embodiment, and FIG. 11 is a plan view in which the flow guide plate is removed in FIG. 10. FIG. 12 is a side view as viewed from the direction of the arrow in FIG. 10. FIG. 13 is a schematic plan view of a main portion of the interior of the reaction chamber when the area of the shield plates is minimized in the parallel plate dry etching apparatus according to the second embodiment. FIG. 14 is a plan view in which the flow guide plate is removed in FIG. 13. FIG. 15 is a side view as viewed from the direction of the arrow in FIG. 13. Components of the same configuration as the configuration described in the first embodiment are marked with the same reference numerals or symbols, and a description thereof is omitted. Differences from the first embodiment are mainly described.

In the parallel plate dry etching apparatus according to the embodiment, the means for altering the area blocking etching gas of the shield plates 11 is different from that of the parallel plate dry etching apparatus according to the first embodiment. As shown in FIG. 9, FIG. 11, and FIG. 12, in the parallel plate dry etching apparatus according to the embodiment, each of the pair of shield plates 11 is composed of three arc-like flat plates 11a to 11c. Each of the three arc-like flat plates 11a to 11c extends along the side wall of the lower electrode 1 in a plane parallel to the upper surface of the lower electrode 1. The three arc-like flat plates 11a to 11c are arranged in three stairs in the direction perpendicular to the upper surface of the lower electrode 1.

A slide means 14 is provided along the side wall of the lower electrode 1 in a plane parallel to the upper surface of the lower electrode 1. The slide means 14 is, for example, a trench-like rail 14 provided on the side wall, and one end on the side of the side wall of the lower electrode 1 of each of the three arc-like flat plates 11a to 11c engages with the trench-like rail 14. By the slide means 14, each of the arc-like flat plates 11a to 11c can be slid independently along the side wall of the lower electrode 1 in a plane parallel to the upper surface of the lower electrode 1.

For example, a first arc-like flat plate 11a of the middle stair out of the three arc-like flat plates is fixed, and a second arc-like flat plate 11b of the upper stair is slid. A third arc-like flat plate 11c of the lower stair is slid in the direction opposite to the direction in which the second arc-like flat plate 11b is slid with respect to the first arc-like flat plate 11a. The second arc-like flat plate 11b is slid while keeping a portion overlapping with the first arc-like flat plate 11a. Similarly, also the third arc-like flat plate 11c is slid while keeping a portion overlapping with the first arc-like flat plate 11a. Thus, by sliding the second arc-like flat plate 11b and the third arc-like flat plate 11c with respect to the first arc-like flat plate 11a, the area with which the shield plates 11 block the flow of etching gas can be changed. That is, the means for altering the area with which the shield plates 11 block etching gas is provided by the three arc-like flat plates 11a to 11c being slid by the slide means.

FIG. 11 is a plan view of a portion including the lower electrode 1 when the three arc-like flat plates 11a to 11c of the shield plate 11 are slid and the area with which the shield plates 11 block etching gas is at the maximum. FIG. 10 shows a state where at this time the shield plates 11 oppose part of the plurality of vent holes 12 of the flow guide plate 5 and block the flow of etching gas. FIG. 12 shows a state of the three arc-like flat plates 11a to 11c as viewed from the direction of the arrow of FIG. 10 at this time.

In contrast, FIG. 14 is a plan view of a portion including the lower electrode 1 when the three arc-like flat plates 11a to 11c overlap and the area with which the shield plates 11 block the flow of etching gas is at the minimum. FIG. 13 shows a state where at this time the shield plates 11 oppose part of the plurality of vent holes 12 of the flow guide plate 5 and block the flow of etching gas. As compared to the state of FIG. 10, the area with which the shield plates 11 oppose vent holes of the flow guide plate 5 is significantly decreased. Thereby, the flow of etching gas can be made close to a uniform radial flow even when the shield plates 11 oppose the flow guide plate 5.

Although the shield plate 11 is composed of the three arc-like flat plates 11a to 11c in the parallel plate dry etching apparatus according to the embodiment, the embodiment is not limited thereto. The shield plate 11 may be composed of four or more arc-like flat plates. When the number of arc-like flat plates is larger, the area with which the shield plates 11 block etching gas can be altered in a wider range.

Also the method for manufacturing a semiconductor device using the parallel plate dry etching apparatus according to the embodiment is similar to the method for manufacturing a semiconductor device according to the first embodiment. Similarly to the case of forming a multiple-layer interconnection layer, in the case of dry etching in which a pattern in a striped configuration is mainly formed, the substrate to be processed 2 is mounted on the lower electrode 1 preferably in such a manner that the direction in which the mask pattern 13 in a striped configuration formed on the surface of the substrate to be processed 2 extends is orthogonal to the first direction in which the pair of shield plates 11 in the parallel plate dry etching apparatus are opposed to each other. In the case of forming a conductive via that electrically connects the interconnection between interconnection layers of a multiple-layer interconnection layer in the vertical direction, dry etching is preferably performed while the pair of shield plates 11 are set such that the area with which the shield plates 11 block the flow of etching gas is minimized as shown in FIG. 14 and FIG. 15.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A parallel plate dry etching apparatus comprising:
a lower electrode having an upper surface in a flat plate form, a substrate being to be mounted on the upper surface in the flat plate form, and the substrate being to be processed;
an upper electrode having a lower surface in a flat plate form opposed to the upper surface of the lower electrode and having a plurality of etching gas supply ports in the lower surface;
a reaction chamber including the lower electrode and the upper electrode in its interior and having an exhaust port to exhaust the etching gas to an opposite side of the lower electrode against the upper electrode;
a flow guide plate disposed in a ring form in an upper portion of a space between a side wall of the reaction chamber and a side wall of the lower electrode, the flow guide plate having a plurality of vent holes to pass through the etching gas, and the flow guide plate surrounding the substrate; and
a pair of shield plates disposed to face the flow guide plate in the space, the pair of shield plates blocking the etching gas passing through part of the plurality of vent holes, and the pair of shield plates facing the lower electrode in a first direction parallel to the upper surface of the lower electrode.

2. The apparatus according to claim 1, wherein the plurality of vent holes are arranged in a circumferential direction of the flow guide plate.

3. The apparatus according to claim 1, wherein the plurality of vent holes extend radially from a center of the flow guide plate.

4. The apparatus according to claim 1, wherein a planar shape of the shield plate includes part of a flat plate in a circular ring form parallel to the upper surface of the lower electrode.

5. The apparatus according to claim 1, wherein the shield plates include a means configured to alter an area blocking the etching gas, and the etching gas passes through the part of the plurality of vent holes.

6. The apparatus according to claim 5, wherein the means fixes one end on the lower electrode side of the shield plate to a side wall of the lower electrode by means of a hinge and
alters the area blocking the etching gas by moving another end opposed to the one end of the shield plate in a direction perpendicular to an upper surface of the lower electrode with the hinge as a fulcrum.

7. The apparatus according to claim 1, wherein a flow in a first direction of the etching gas from a center of the substrate toward an outside of the substrate is suppressed as compared to a flow of the etching gas in a second direction orthogonal to the first direction when part of the plurality of vent holes are blocked by the shield plates.

8. The apparatus according to claim 5, wherein the means
configures the shield plate out of a plurality of arc-like flat plates extending along a side wall of the lower electrode in a plane parallel to the upper surface of the lower electrode,
arranges the plurality of arc-like flat plates in a direction perpendicular to the upper surface of the lower electrode, and
alters the area blocking the etching gas by sliding each of the plurality of arc-like flat plates along a side wall of the lower electrode in a plane parallel to the upper surface of the lower electrode by means of a slide means provided along a side wall of the lower electrode.

9. The apparatus according to claim 8, wherein the plurality of arc-like flat plates include at least a first flat plate, a second flat plate, and a third flat plate and
the third flat plate slides in a first direction opposite to a second direction, the second flat plate slides in the second direction with respect to the first flat plate.

10. A method for manufacturing a semiconductor device comprising dry-etching a surface of a substrate to be processed using a parallel plate dry etching apparatus,
the apparatus including a lower electrode having an upper surface in a flat plate form, a substrate being to be mounted on the upper surface in the flat plate form, and the substrate being to be processed; an upper electrode having a lower surface in a flat plate form opposed to the upper surface of the lower electrode and having a plurality of etching gas supply ports in the lower surface; a reaction chamber including the lower electrode and the upper electrode in its interior and having an exhaust port to exhaust the etching gas to an opposite side of the lower electrode against the upper electrode; a flow guide plate disposed in a ring form in an upper portion of a space between a side wall of the reaction chamber and a side wall of the lower electrode, the flow guide plate having a plurality of vent holes to pass through the etching gas, and the flow guide plate surrounding the substrate; and a pair of shield plates disposed to face the flow guide plate in the space, the pair of shield plates blocking the etching gas passing through part of the plurality of vent holes, and the pair of shield plates facing the lower electrode in a first direction parallel to the upper surface of the lower electrode,
the substrate having a mask pattern in a striped configuration,
the method including etching the surface of the substrate using the apparatus while mounting the substrate on the upper surface of the lower electrode in such a manner that a direction in which a stripe of the mask pattern extends is orthogonal to the first direction in the apparatus.

11. The method according to claim 10, wherein the shield plates alter an area blocking the etching gas passing through the part of the plurality of vent holes.

12. The method according to claim 11, wherein one end on the lower electrode side of the shield plate is fixed to a side wall of the lower electrode by a hinge and
the area blocking the etching gas is altered by moving another end opposed to the one end of the shield plate in a direction perpendicular to an upper surface of the lower electrode with the hinge as a fulcrum.

13. The method according to claim 10, wherein a flow in the first direction of the etching gas from a center of the substrate toward an outside of the substrate is suppressed as compared to a flow of the etching gas in a second direction orthogonal to the first direction when part of the plurality of vent holes are blocked by the shield plates.

14. The method according to claim 11, wherein
the shield plate includes a plurality of arc-like flat plates extending along a side wall of the lower electrode in a plane parallel to the upper surface of the lower electrode,
the plurality of arc-like flat plates are arranged in a direction perpendicular to the upper surface of the lower electrode, and
the area blocking the etching gas is altered by sliding each of the plurality of arc-like flat plates along a side wall of the lower electrode in a plane parallel to the upper surface of the lower electrode by means of a slide means provided along a side wall of the lower electrode.

15. The method according to claim 14, wherein the plurality of arc-like flat plates include at least a first flat plate, a second flat plate, and a third flat plate and the third flat plate is slid in a first direction opposite to a second direction, the second flat plate slides in the second direction with respect to the first flat plate.
